(19) United States
(12) Patent Application Publication
(10) Pub. No.: US 2026/0271532 A1
(43) Pub. Date: Sep. 10, 2026

(54) Display Device, Electronic Device And Method For Fabricating The Same

(71) Applicant: Samsung Display Co., Ltd., Yongin-si (KR)

(72) Inventors: In Woo Kim, Yongin-si (KR); Jong Hoon Lee, Yongin-si (KR); Young Geol Song, Yongin-si (KR)

(73) Assignee: Samsung Display Co., Ltd., Yongin-si (KR)

(21) Appl. No.: 19/347,929

(22) Filed: Oct. 2, 2025

(30) Foreign Application Priority Data
Mar. 6, 2025 (KR) 10-2025-0028972

(51) Int. Cl. H10K 59/122; H10K 59/12

(52) U.S. Cl. CPC H10K 59/122; H10K 59/1201

(57) ABSTRACT

A display device includes a substrate having an emission area and a non-emission area. An anode electrode is located on the emission area of the substrate. A pixel-defining layer is located over the anode electrode and defines a first trench recessed toward the substrate. Additionally, a spacer is located on the pixel-defining layer and defines a second trench recessed toward the pixel-defining layer. The first trench and the second trench overlap each other in a direction perpendicular to a surface of the substrate, and a width of the first trench is greater than a width of the second trench.

This application claims priority from Korean Patent Application No. 10-2025-0028972 filed on Mar. 6, 2025, in the Korean Intellectual Property Office, the disclosure of which is incorporated herein by reference in its entirety.

### TECHNICAL FIELD

The present disclosure relates to a display device, an electronic device using the same, and a method for fabricating a display device.

### BACKGROUND

As the information-oriented society evolves, various demands for display devices are ever increasing. A display device may be a flat-panel display device such as a liquid-crystal display device, a field emission display device, or a light-emitting display device. Light-emitting display devices may include an organic light-emitting display device including organic light-emitting emitting diodes (OLED) as light-emitting elements, or an light-emitting diode display device including inorganic light-emitting diodes such as light-emitting diodes (LEDs) as light-emitting elements.

Display devices employing two-stack tandem OLED technology are being developed, in which an upper emissive layer is stacked on a lower emissive layer. A display device employing the two-stack tandem OLED technology can provide a high-brightness display screen by combining lights generated from the two layers (i.e., the lower emissive layer and the upper emissive layer). However, such variations of OLED technology may suffer from leakages of current from emission areas of the display device.

Accordingly, a need exists for display devices that provide a high-brightness display while also not being susceptible to leakage current.

### BRIEF SUMMARY

Aspects of the present disclosure provide a display device that is not susceptible to leakage current defects caused by light-emitting elements and damage in a pixel-defining layer that may occur during the fabrication process.

It should be noted that objects of the present disclosure are not limited to the above-mentioned object; and other objects of the present disclosure will be apparent to those skilled in the art from the following descriptions.

The details of one or more embodiments of the subject matter described in this specification are set forth in the accompanying drawings and the description below.

In an embodiment of the disclosure, a display device includes a substrate. The substrate includes an emission area and a non-emission area. An anode electrode is located on the emission area of the substrate. A pixel-defining layer is located over the anode electrode and defines a first trench recessed toward the substrate. A spacer is located on the pixel-defining layer and defines a second trench recessed toward the pixel-defining layer. The first trench and the second trench overlap each other in a direction perpendicular to a surface of the substrate, and a width of the first trench is greater than a width of the second trench.

In an embodiment, the pixel-defining layer may cover an edge of the anode electrode, and the pixel-defining layer is entirely covered by the spacer.

In an embodiment, the pixel-defining layer may comprise an upper surface facing the spacer and a side surface facing the emission area and connected to the upper surface. The spacer may be in contact with the upper surface and the side surface of the pixel-defining layer to cover them.

In an embodiment, the pixel-defining layer may define an emission opening, wherein the pixel-defining layer exposes the anode electrode in the emission opening. In this arrangement, the first trench and the second trench do not overlap with the emission opening.

In an embodiment, the spacer may be in contact with the anode electrode in the emission opening.

In an embodiment, the display device may further comprise an organic layer located on the anode electrode in the emission opening. The organic layer may be located in contact with the spacer, and the organic layer includes a step in the second trench. Put another way, a surface of the organic layer follows the step in the second trench.

In an embodiment, the display device may further comprise a cathode electrode located above the anode electrode. The cathode electrode may include a step in the second trench. Put another way, a surface of the cathode electrode follows the step in the second trench.

In an embodiment, an edge of a surface of the spacer in the second trench may overlap with the first trench.

In an embodiment, the display device may further comprise a protrusion protruding in the direction perpendicular to the surface of the substrate. In this arrangement, the first trench and the second trench do not overlap with the protrusion.

In an embodiment of the present disclosure, a method of fabricating a display device may be performed. In one example of the method, the method includes: forming a pixel-defining layer comprising a first trench on an anode electrode included in a substrate; forming a spacer comprising a protrusion on the pixel-defining layer; forming a second trench in the spacer; and forming an organic layer and a cathode electrode over the anode electrode.

In an embodiment, the forming of the pixel-defining layer comprising the first trench on the anode electrode comprises: forming the first trench by a photolithography process using a halftone mask, where the first trench may be formed by a portion of the pixel-defining layer that is recessed toward the substrate.

In an embodiment, the forming of the spacer comprising the protrusion on the pixel-defining layer may comprise forming the protrusion of the spacer by a photolithography process, where the protrusion of the spacer does not overlap with the first trench.

In an embodiment, the forming of the second trench in the spacer may comprise forming the second trench by performing a dry etching process, where the second trench may be formed by a portion of the spacer that is recessed toward the pixel-defining layer.

In an embodiment, the forming of the second trench in the spacer may comprise forming the second trench so that the first trench and the second trench overlap each other in a direction perpendicular to a surface of the substrate.

In an embodiment, the forming of the organic layer and the cathode electrode over the anode electrode may comprise forming the organic layer and the cathode electrode so that they overlap with the first trench and the second trench, where the organic layer comprises a tandem structure, and the cathode electrode may be a common electrode.

In an embodiment of the disclosure, an electronic device includes a display device and at least one of a display module, a processor, a memory or a power module connected to the display device. The display device includes a substrate having an emission area and a non-emission area. Further, the display device also includes: an anode electrode located on the emission area of the substrate; a pixel-defining layer located over the anode electrode and comprising a first trench recessed toward the substrate; and a spacer located on the pixel-defining layer and comprising a second trench recessed toward the pixel-defining layer. The first trench and the second trench overlap each other in a direction perpendicular to a surface of the substrate, and a width of the first trench is greater than a width of the second trench.

According to an embodiment of the present disclosure, by forming a first trench included in a pixel-defining layer and a second trench included in a spacer such that the respective trenches overlap with each other in a direction perpendicular to a surface of the substrate, the leakage current defects that may otherwise be caused by light-emitting elements can be prevented.

In addition, according to an embodiment of the present disclosure, by forming a spacer including a second trench in a display device, it is possible to prevent damage to a pixel-defining layer that may otherwise occur during the fabrication process.

It should be appreciated that the effects and advantages of the present disclosure are not limited to those described above and that other effects and advantages of the present disclosure will be apparent to those skilled in the art from the following descriptions.

### BRIEF DESCRIPTION ON THE DRAWINGS

The above and other aspects and features of the present disclosure will become more apparent by describing in detail embodiments thereof with reference to the attached drawings, in which:

FIG. 1 is a perspective view of a display device according to an embodiment of the present disclosure.

FIG. 2 is a cross-sectional view of the display device according to an embodiment of the present disclosure.

FIG. 3 is a schematic plan view of the display layer of FIG. 2.

FIG. 4 is an enlarged plan view of a portion of the display area of FIG. 3.

FIG. 5 is a cross-sectional view showing a plurality of light-emitting elements in the display arca of FIG. 4.

FIG. 6 is a cross-sectional view taken along line Y1 - Y1' of the display area of FIG. 4.

FIG. 7 is an enlarged cross-sectional view of arca A of FIG. 6.

FIG. 8 is a flowchart illustrating steps in a method of fabricating the display element layer of FIG. 6.

FIGS. 9 and 10 are cross-sectional views of the partially formed display element layer in step S100 of the method of FIG. 8.

FIGS. 11 and 12 are cross-sectional views of the partially formed display element layer in step S200 of the method of FIG. 8.

FIGS. 13 and 14 are cross-sectional views of the partially formed display element layer in step S300 of the method of FIG. 8.

FIG. 15 is a cross-sectional view of the display element layer in step S400 of the method of FIG. 8.

FIG. 16 is a block diagram of an electronic device according to an embodiment of the present disclosure.

FIG. 17 illustrates perspective views of electronic devices according to a variety of embodiments of the present disclosure.

### DETAILED DESCRIPTION

Advantages and features of the present disclosure and methods of accomplishing the same may be understood more readily by reference to the following detailed description of embodiments and the accompanying drawings. The present disclosure may, however, be embodied in many different forms and should not be construed as being limited to the embodiments set forth herein. Rather, these embodiments are provided so that this disclosure will be thorough and complete and will fully convey the concept of the present disclosure to those skilled in the art.

It will be understood that when an element or layer is referred to as being "on” another element or layer, the element or layer can be directly on another element or layer or the element can be on intervening elements or layers. Like reference numerals refer to like elements throughout the present disclosure. Shapes, sizes, ratios, angles, numbers, etc. disclosed in the drawings for describing embodiments are merely examples for purposes of illustration, and the present disclosure is not limited to the illustrated details.

It will be understood that, although the terms first, second, third, etc., may be used herein to describe various elements, elements referenced in such manner should not be limited by these terms. These terms are only used to distinguish one element from another element. Thus, a first element discussed below for one embodiment or example could be termed a second element when referenced in another embodiment or example without departing from the teachings of the present disclosure.

Features of various embodiments of the present disclosure may be partially or entirely coupled to or combined with each other, and may be inter-operated and driven in a variety of technical arrangements. The embodiments may be implemented independently from each other, or may be implemented together in a co-dependent relationship.

Hereinafter, embodiments of the present disclosure will be described in detail with reference to the accompanying drawings.

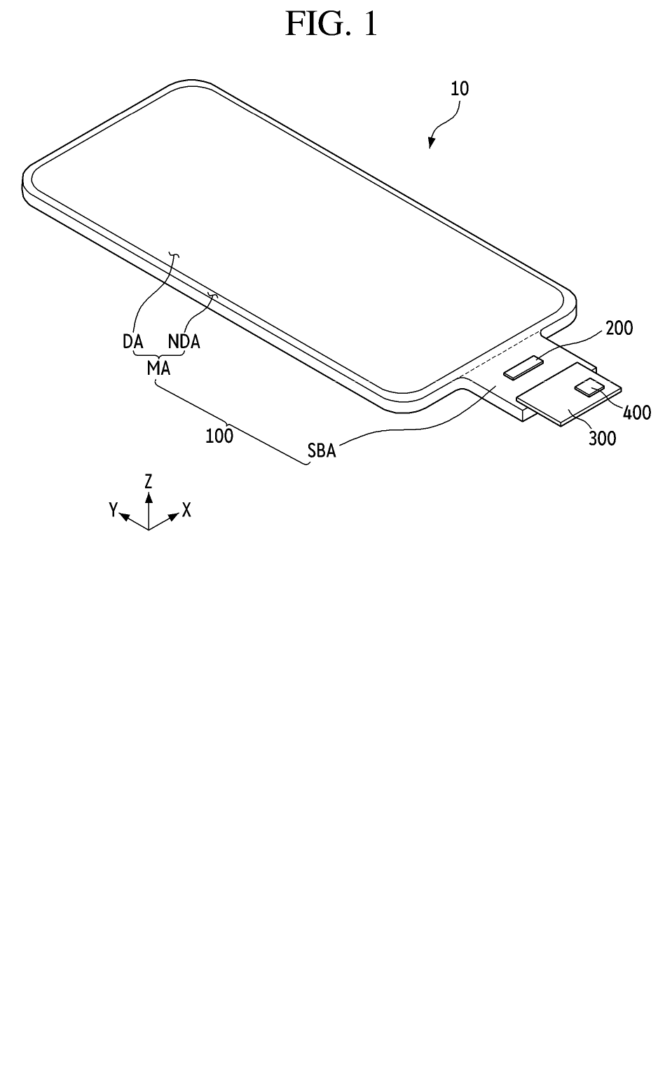

FIG. 1 is a perspective view of a display device according to an embodiment of the present disclosure.

Referring to FIG. 1, a display device 10 may be employed by (and incorporated into) portable electronic devices such as a mobile phone, a smart phone, a tablet PC, a mobile communications terminal, an electronic notebook, an electronic book, a portable multimedia player (PMP), a navigation device or an ultra mobile PC (UMPC). For example, the display device 10 may be used as a display unit of a television, a laptop computer, a monitor, an electronic billboard, or for the Internet of Things (IOT). For another example, the display device 10 may be applied to wearable devices such as a smart watch, a watch phone, a glasses-type display, or a head-mounted display (HMD) device.

The display device 10 may have a shape resembling a quadrangular shape when viewed from above or the top, i.e., a direction perpendicular to a display surface. For example, the display device 10 may have a shape similar to a quadrangle having shorter sides in a first direction (x-axis direction) and longer sides in a second direction (y-axis direction) when viewed from the top. Each of the corners where the short side in the first direction (x-axis direction) meets the longer side in the second direction (y-axis direction) may be rounded with a predetermined curvature or may be a right angle. The shape of the display device 10 when viewed from the top is not limited to a quadrangular shape, and may instead be formed in a shape similar to other polygonal shapes, a circular shape, or an elliptical shape

The display device 10 may include a display panel 100, a display driver 200, a circuit board 300 and a touch driver 400.

The display panel 100 may include a main area MA and a subsidiary area SBA. The main area MA may include the display area DA including pixels for displaying images, and the non-display area NDA located around the display area DA.

The display area DA may emit light from a plurality of emission areas or a plurality of openings to be described later. For example, the display panel 100 may include pixel circuits including switching elements, an element insulating layer that defines the emission areas or the openings, and self-light-emitting elements. For example, the self-light-emitting element may include, but is not limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, or a micro light-emitting diode (micro LED). In the following drawings, the self-light emitting element is illustrated as an organic light-emitting diode.

The non-display area NDA may be located on the outer side of the display area DA, e.g., outside of an outer perimeter of the display area DA. The non-display area NDA may be defined as the edge area of the main area MA of the display panel 100.

The subsidiary area SBA may extend from one side of the main area MA. The subsidiary area SUB may include a flexible material that can be bent, folded, or rolled. For example, when the subsidiary area SBA is bent, the subsidiary area SBA may overlap the main area MA in a thickness direction (e.g., a third direction or z-axis direction). The subsidiary area SBA may include pads connected to the display driver 200 and the circuit board 300. According to another embodiment, the subsidiary area SBA may be eliminated, and the display driver 200 and the pads may be disposed in the non-display area NDA.

The display driver 200 may output signals and voltages for driving the display panel 100. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be located in the subsidiary area SBA and may overlap with the main area MA in the thickness direction as the subsidiary area SBA is bent. In another example, the display driver 200 may be mounted on the circuit board 300.

The circuit board 300 may be attached on the pad area of the display panel 100 using an anisotropic conductive film (ACF). The circuit board 300 may be a flexible printed circuit board (FPCB), a printed circuit board (PCB), or a flexible film such as a chip-on-film (COF).

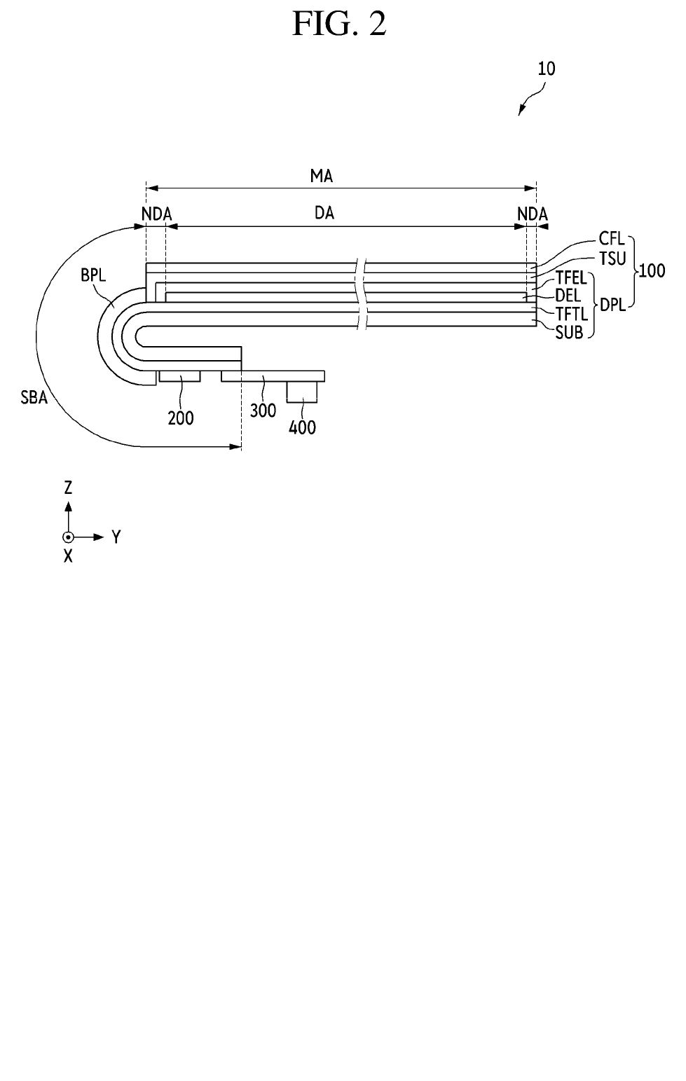

The touch driver 400 may be mounted on the circuit board 300. The touch driver 400 may be connected to a touch sensor layer, or touch layer TSU (see FIG. 2) for touch sensing and driving.

FIG. 2 is a cross-sectional view of the display device according to an embodiment of the present disclosure.

Referring to FIG. 2, the display panel 100 may include a display layer DPL, a touch layer TSU, and a color filter layer CFL. The display layer DPL may include a substrate SUB, a transistor layer TFTL, a display element layer DEL, and a thin-film encapsulation layer TFEL.

The substrate SUB may be a base substrate or a base member. The substrate SUB may be a flexible substrate that can be bent, folded, or rolled. For example, the substrate SUB may include, but is not limited to, a polymer resin such as polyimide PI. According to another embodiment, the substrate SUB may include a glass material or a metal material.

The transistor layer TFTL may be disposed on the substrate SUB. The transistor layer TFTL may be located in the display area DA, the non-display area NDA and the subsidiary area SBA.

The display element layer DEL may be located on the transistor layer TFTL, i.e., disposed on the transistor layer TFTL. Throughout the present disclosure, references to a layer of the display device 10 being located on another layer of the display device may also be described as the layer being disposed on the other layer. The display element layer DEL may be located in the display area DA. The display element layer DEL may include, but is not limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, or a micro light-emitting diode (micro LED).

The thin-film encapsulation layer TFEL may be located on the display element layer DEL. The thin-film encapsulation layer TFEL may be disposed in the display area DA and the non-display area NDA. The thin-film encapsulation layer TFEL may cover the upper and side surfaces of the display element layer DEL, and can protect the display element layer DEL from outside oxygen and moisture. The thin-film encapsulation layer TFEL may include at least one inorganic film and at least one organic film for encapsulating the display element layer DEL. The thin-film encapsulation layer TFEL may be eliminated in some implementations.

The touch layer TSU may be located on the thin-film encapsulation layer TFEL. The touch layer TSU may be located across the display area DA and the non-display area NDA. The touch layer TSU may sense a user's touch by mutual capacitance sensing or self-capacitance sensing. In some implementations, the touch layer TSU may be eliminated.

The color filter layer CFL may be located on the touch layer TSU. The color filter layer CFL may be located in the display area DA and the non-display area NDA. The color filter layer CFL may absorb some of lights introduced from the outside of the display device 10 to reduce the reflection of external light. Accordingly, the color filter layer CFL can prevent distortion of colors due to the reflection of external light.

Since the color filter layer CFL is located directly on the touch layer TSU, the display device 10 may require no separate substrate for the color filter layer CFL. Therefore, the thickness of the display device 10 can be relatively small. The color filter layer CFL may be eliminated in some implementations.

As shown in FIG. 2, a portion of the display panel 100 overlapping with the subsidiary area SBA may be bent. When a portion of the display panel 100 is bent, the display driver 200, the circuit board 300 and the touch driver 400 may overlap with the main area MA in the third direction (z-axis direction).

When a part of the display panel 100 is bent, the bending protection layer BPL can protect the underlying structures located in the subsidiary area SBA from bending stress.

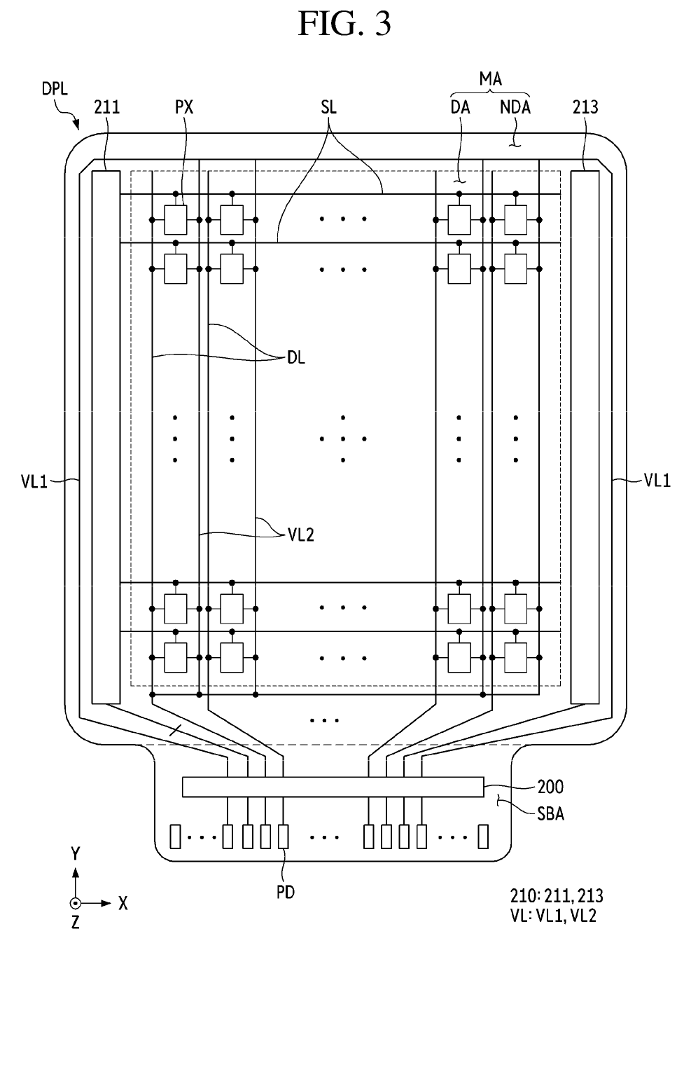

FIG. 3 is a schematic plan view of the display layer of FIG. 2.

Referring to FIG. 3, the display layer DPL may include a plurality of pixels PX, a plurality of scan lines SL, a plurality of data lines DL, and a plurality of second voltage lines VL2 in the display area DA of the main area MA.

Each of the plurality of pixels PX may be defined as the minimum unit that outputs light. Each of the plurality of pixels PX may be connected to at least one scan line SL, at least one data line DL, and at least one voltage line VL. Although the pixels PX are arranged on the same lines, i.e., along a linear alignment in the first direction (x-axis direction) and in the second direction (y-axis direction) in the drawing, such arrangement is presented for convenience of illustration, and is merely an example for drawing the circuit diagram. Accordingly, it should be understood that the embodiments of the present disclosure are not limited thereto.

The scan lines SL may provide the scan signals applied from the scan driver 210 for each horizontal line to the plurality of pixels PX. The scan lines SL may be extended in the first direction (x-axis direction) and may be spaced apart from each other in the second direction (y-axis direction).

The plurality of data lines DL may supply the data voltages received from the display driver 200 to the plurality of pixels PX. The plurality of data lines DL may be extended in the second direction (y-axis direction) and may be spaced apart from each other in the first direction (x-axis direction).

The second voltage lines VL2 may apply the supply voltage received from the first voltage line VL1 to the plurality of pixels PX. The supply voltage may be at least one of a driving voltage, an initialization voltage, or a reference voltage. The second voltage lines VL2 may be extended in the second direction (y-axis direction) and may be spaced apart from each other in the first direction (x-axis direction).

The display layer DPL may include the first voltage line VL1 and the scan driver 210 in the non-display area NDA of the main area MA.

The first voltage line VL1 may apply the supply voltage received from the display driver 200 to the plurality of pixels PX through the second voltage lines VL2.

The scan driver 210 may include a first scan driver 211 and a second scan driver 213. The first scan driver 211 may be located on one side (e.g., the left side) of the display layer DPL, and the second scan driver 213 may be located on the opposite side (e.g., the right side) of the display layer DPL. It should be understood, however, that the present disclosure is not limited thereto. Each of the first scan driver 211 and the second scan driver 213 may receive a scan control signal from the display driver 200, and may generate scan signals in response to the scan control signal to output the scan signals to the scan lines SL.

The display layer DPL may include the display driver 200 and a plurality of pad electrodes PD located in the subsidiary area SBA. The pad electrodes PD may be spaced apart from one another in the first direction (x-axis direction), and the pad electrodes PD may be connected to different lines, respectively.

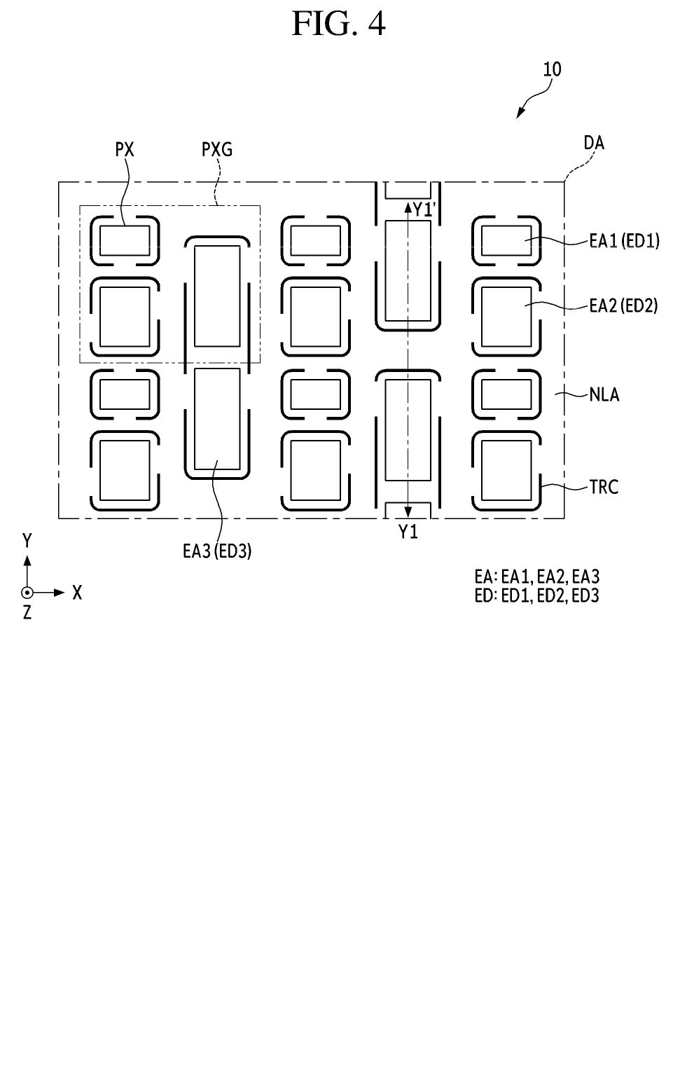

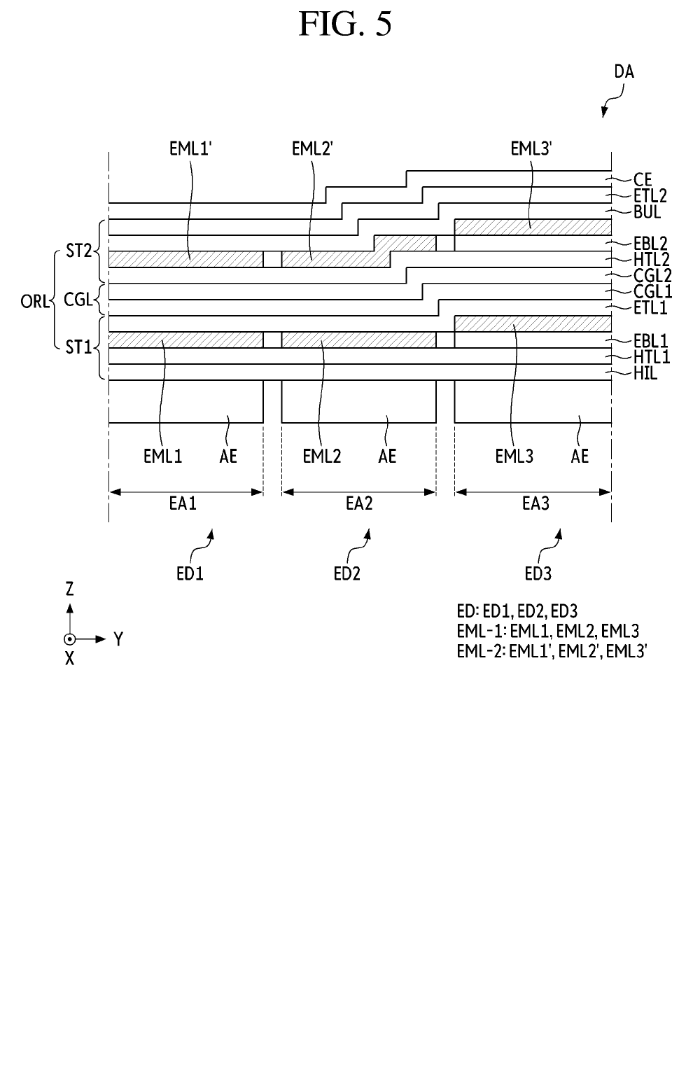

FIG. 4 is an enlarged plan view of the display area of FIG. 3. FIG. 5 is a cross-sectional view showing a plurality of light-emitting elements in FIG. 4.

Referring to FIGS. 4 and 5, the display device 10 according to the embodiment may include a plurality of pixels PX in the display area DA. The pixels PX may be spaced apart from one another. Each of the pixels PX may include a light-emitting element ED.

The light-emitting elements ED may include a first light-emitting element ED1, a second light-emitting element ED2, and a third light-emitting element ED3 that are spaced apart from each other. According to an embodiment of the present disclosure, the first to third light-emitting elements ED1, ED2 and ED3 may emit lights of the same color or may emit lights of different colors. For example, the first to third light-emitting elements ED1, ED2 and ED3 may include a tandem structure. More detailed descriptions will be given below.

The first to third light-emitting elements ED1, ED2 and ED3 may include first to third emission areas EA1, EA2 and EA3, respectively. The first to third emission areas EA1, EA2 and EA3 may output lights of the same color or may output lights of different colors.

As shown in FIG. 4, at least one first light-emitting element ED1, at least one second light-emitting element ED2 and at least one third light-emitting element ED3 arranged adjacent to each other may form a pixel group PXG. The type and/or number of the first to third light-emitting elements ED1, ED2 and ED3 forming a pixel group PXG may vary for different embodiments. A pixel group PXG may be the minimum unit that outputs white light.

The non-emission area NLA may be located such that it surrounds the emission areas EA. The non-emission area NLA can help prevent the lights emitted from the first to third emission areas EA1, EA2 and EA3 from being mixed.

A trench TRC may be located to partially surround a light-emitting element ED when viewed from the top, i.e., when viewed from above in the third direction (z-axis direction). The trench TRC may be located in the non-emission area NLA. The trench TRC will be described in further detail below.

As shown in FIG. 5, a light-emitting element ED according to the embodiment may include an anode electrode AE, an organic layer ORL, and a cathode electrode CE.

According to an embodiment, there may be a plurality of anode electrodes AE. The anode electrodes AE may be located in the first to third emission areas EA1, EA2 and EA3, respectively, and may be spaced apart from each other.

The organic layer ORL according to the embodiment may be located on the anode electrode AE. The organic layer ORL may be formed in a tandem structure. In other words, the organic layer ORL may include a first stack ST1, a charge generation layer CGL and a second stack ST2 stacked in the third direction (z-axis direction).

The first stack ST1 according to the embodiment may be located on the anode electrode AE. The first stack ST1 may include a hole injection layer HIL, a first hole transport layer HTL1, a first electron block layer EBL1, a lower emissive layer EML-1, and a first electron transport layer ETL1.

The hole injection layer HIL according to the embodiment may be in contact with the anode electrode AE. The hole injection layer HIL may be a common layer that is continuously extended across the first emission area EA1, the second emission area EA2 and the third emission area EA3. The hole injection layer HIL may include a hole injection material that facilitates hole injection. The hole injection layer HIL may be eliminated in some implementations.

For example, the hole injection material may be made of, but is not limited to, at least one compound selected from the group consisting of: CuPc (copper phthalocyanine), PEDOT (poly(3,4)-ethylenedioxythiophene), PANI (polyaniline) or NPD (N,N-dinaphthyl-N,N'-diphenyl benzidine).

According to the embodiment depicted in FIG. 5, the first hole transport layer HTL1 may be located in contact with the hole injection layer HIL. The first hole transport layer HTL1 may be a common layer that is continuously extended across the first emission area EA1, the second emission area EA2 and the third emission area EA3. The first hole transport layer HTL1 may include a hole transport material that facilitates hole transport.

The hole transport material may include, but is not limited to, carbazole derivatives such as N-phenylcarbazole and polyvinylcarbazole, fluorene derivatives, triphenylamine derivatives such as TPD(N,N'-bis(3-methylphenyl)-N,N'-diphenyl-[1,1-biphenyl]-4,4'-diamine) and TCTA(4,4',4"-tris(N -carbazolyl)triphenylamine), NPB(N,N'-di(1-naphthyl)-N,N'-diphenylbenzidine), TAPC(4,4′-Cyclohexylidene bis[N,N-bis(4-methylphenyl)benzenamine]), etc.

According to the embodiment, the first electron block layer EBL1 may be located in contact with the first hole transport layer HTL1. In some implementations, the first electron block layer EBL1 and the first hole transport layer HTL1 may be formed as a single layer.

The first electron block layer EBL1 can prevent electrons generated in the lower emissive layer EML-1 from flowing over to the first hole transport layer HTL1. The first electron block layer EBL1 may be formed by including the above-described hole transport material and a metal or a metal compound. Although the first electron block layer EBL1 is located only in the third emission area EA3 in the drawings, the present disclosure is not limited thereto.

According to the embodiment, the lower emissive layer EML-1 may be located on the first electron block layer EBL1 and the first hole transport layer HTL1. The lower emissive layer EML-1 may include a first lower emissive layer EML1, a second lower emissive layer EML2, and a third lower emissive layer EML3. The first lower emissive layer EML1, the second lower emissive layer EML2 and the third lower emissive layer EML3 may be spaced apart from each other in the first direction (x-axis direction).

The first lower emissive layer EML1, the second lower emissive layer EML2 and the third lower emissive layer EML3 may emit lights of different colors. For example, the first lower emissive layer EML1 may emit red light, the second lower emissive layer EML2 may emit green light, and the third lower emissive layer EML3 may emit blue light.

According to the embodiment, the first electron transport layer ETL1 may be located on the lower emissive layer EML-1. The first electron transport layer ETL1 may be a common layer that is continuously extended across the first emission area EA1, the second emission area EA2 and the third emission area EA3. The first electron transport layer ETL1 may include an electron transport material that facilitates the transport of electrons.

For example, the electron transport material may include, but is not limited to, electron transparent material such as Alq3(Tris(8-hydroxyquinolinato)aluminum), TPBi(1,3,5-Tri(1-phenyl-1H-benzo[d]imidazol-2-yl)phenyl), BCP(2,9-Dimethyl-4,7-diphenyl-1,10-phenanthroline), Bphen(4,7-Diphenyl-1,10-phenanthroline), TAZ(3-(4-Biphenylyl)-4-phenyl-5-tert-butylphenyl-1,2,4-triazole), NTAZ(4-(Naphthalen-1-yl)-3,5-diphenyl-4H-1,2,4-triazole), tBu-PBD(2-(4-Biphenylyl)-5-(4-tert-butylphenyl)-1,3,4-oxadiazole), BAlq(Bis(2-methyl-8-quinolinolato-N1,O8)-(1,1'-Biphenyl-4-olato)aluminum), Bebq2(berylliumbis(benzoquinolin-10-olate), ADN(9,10-di(naphthalene-2-yl)anthracene) and a mixture thereof.

According to the embodiment, the charge generation layer CGL may be placed on the first stack ST1. The charge generation layer CGL may be a common layer that is extended continuously across the first emission area EA1, the second emission area EA2 and the third emission area EA3.

The charge generation layer CGL may control charge balance between the first stack ST1 and the second stack ST2. In other words, the charge generation layer CGL is located between the first stack ST1 and the second stack ST2, so that the emission efficiency of the light-emitting element ED can be increased and the driving voltage can be lowered.

The charge generation layer CGL may include a first charge generation layer CGL1 and a second charge generation layer CGL2. According to the embodiment, the first charge generation layer CGL1 may be closer to the anode electrode AE than the second charge generation layer CGL2 and may supply electrons to the lower emissive layer EML-1. According to the embodiment, the second charge generation layer CGL2 may be closer to the cathode electrode CE than the first charge generation layer CGL1 and may supply holes to the upper emissive layer EML-2.

According to the embodiment, the second stack ST2 may be placed on the charge generation layer CGL. The second stack ST2 may include a second hole transport layer HTL2, a second electron block layer EBL2, an upper emissive layer EML-2, a buffer layer BUL and a second electron transport layer ETL2.

According to the embodiment of the present disclosure, the second hole transport layer HTL2 may be located in contact with the charge generation layer CGL. The second hole transport layer HTL2 may be a common layer that is continuously extended across the first emission area EA1, the second emission area EA2 and the third emission area EA3.

The second hole transport layer HTL2 may be made of the same material as the first hole transport layer HTL1 or may include one or more materials selected from the materials included in the first hole transport layer HTL1. The second hole transport layer HTL2 may be made up of a single layer or multiple layers.

The second electron block layer EBL2 may be located on the second hole transport layer HTL2. In some implementations, the second electron block layer EBL2 and the second hole transport layer HTL2 may be formed as a single layer.

The second electron block layer EBL2 may include the hole transport material and a metal or a metal compound to prevent the electrons generated in the upper emissive layer EML-2 from flowing into the second hole transport layer HTL2. Although the second electron block layer EBL2 is located only in the third emission area EA3 in the drawings, the present disclosure is not limited thereto.

According to the embodiment, the upper emissive layer EML-2 may be located on the second electron block layer EBL2 and the second hole transport layer HTL2. The upper emissive layer EML-2 may include a first upper emissive layer EML1', a second upper emissive layer EML2', and a third upper emissive layer EML3'. The first upper emissive layer EML1', the second upper emissive layer EML2' and the third upper emissive layer EML3' may be spaced apart from each other in the first direction (x-axis direction).

The first upper emissive layer EML1', the second upper emissive layer EML2' and the third upper emissive layer EML3' may overlap with the first lower emissive layer EML1, the second lower emissive layer EML2 and the third lower emissive layer EML3 in the third direction (z-axis direction), respectively.

The first upper emissive layer EML1', the second upper emissive layer EML2' and the third upper emissive layer EML3' may emit lights of different colors. For example, the first upper emissive layer EML1' may emit red light, the second upper emissive layer EML2' may emit green light, and the third upper emissive layer EML3' may emit blue light.

Any low-molecular organic material or high-molecular organic material well known in the art may be used as the material included in the lower emissive layer EML-1 and the upper emissive layer EML-2.

The buffer layer BUL according to the embodiment may be located on the upper emissive layer EML-2. The buffer layer BUL may be a common layer that is continuously extended across the first emission area EA1, the second emission area EA2 and the third emission area EA3.

The buffer layer BUL can prevent holes from flowing from the upper emissive layer EML-2 toward the cathode electrode CE. The buffer layer BUL may include, but is not limited to, a hole transport material.

According to the embodiment, the second electron transport layer ETL2 may be placed on the buffer layer BUL. The second electron transport layer ETL2 may be a common layer that is continuously extended across the first emission area EA1, the second emission area EA2 and the third emission area EA3.

The second electron transport layer ETL2 may be made of the same material and the same structure as the first electron transport layer ETL1, or may include one or more materials selected from the materials included in the first electron transport layer ETL1. The second electron transport layer ETL2 may be made up of a single layer or multiple layers.

According to the embodiment, the cathode electrode CE may be located in contact with the organic layer ORL. The cathode electrode CE may be a common electrode that continuously extends across the first emission area EA1, the second emission area EA2 and the third emission area EA3.

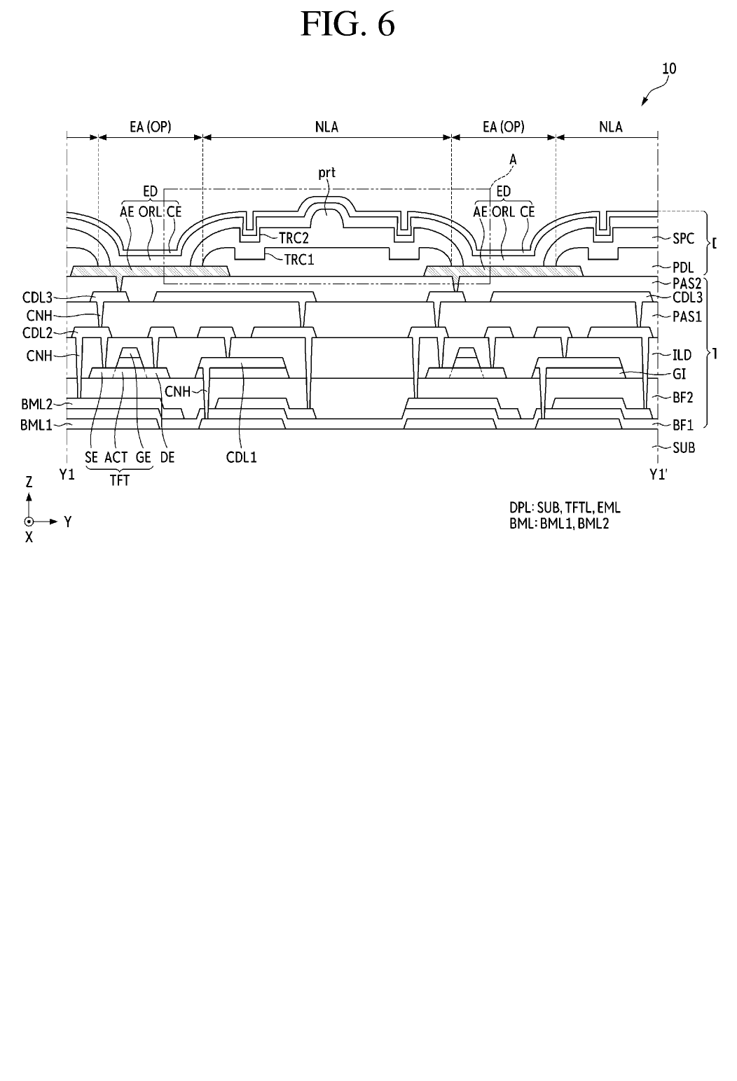

FIG. 6 is a cross-sectional view taken along line Y1 - Y1' of the display area of FIG. 4. More specifically, FIG. 6 is a cross-sectional view of the substrate SUB, a thin-film transistor layer TFTL, and a display element layer DEL of the display layer DPL included in the display device 10. Although not shown in the drawing, the display device 10 according to the embodiment may further include the thin-film encapsulation layer TFEL, the touch layer TSU and the color filter layer CFL shown in FIG. 2 disposed on the display element layer DEL.

Referring to FIG. 6 in conjunction with FIGS. 1 to 5, the substrate SUB may be a base substrate or a base member. The substrate SUB may be a flexible substrate that can be bent, folded, or rolled. For example, the substrate SUB may include, but is not limited to, a polymer resin such as polyimide PI. The substrate SUB may include a glass material or a metal material.

The thin-film transistor layer TFTL may be located on the substrate SUB. The thin-film transistor layer TFTL may include a first bottom metal layer BML1, a first buffer layer BF1, a second bottom metal layer BML2, a second buffer layer BF2, a thin-film transistor TFT, a first conductive layer CDL1, a gate insulator GI, an interlayer dielectric layer ILD, a second conductive layer CDL2, a first passivation layer PAS1, a third conductive layer CDL3, and a second passivation layer PAS2.

The first bottom metal layer BML1 may be located on the substrate SUB. The first bottom metal layer BML1 may be arranged such that it overlaps with at least one of the thin-film transistor TFT and/or the first conductive layer CDL1 in the third direction (z-axis direction). The first bottom metal layer BML1 can prevent light from entering the active layer ACT of the thin-film transistor TFT, and may be electrically connected to the first conductive layer CDL1 to perform the function of stabilizing the characteristics of the first conductive layer CDL1.

The first bottom metal layer BML1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first buffer layer BF1 may be located on the first bottom metal layer BML1. The first buffer layer BF1 may entirely cover the substrate SUB and the first bottom metal layer BML1. The first buffer layer BF1 may include an inorganic film capable of preventing permeation of air or moisture. For example, the first buffer layer BF1 may include a plurality of inorganic films stacked on one another alternately.

The second bottom metal layer BML2 may be located on the first buffer layer BF1. The second bottom metal layer BML2 may be arranged such that it overlaps with at least one of the thin-film transistor TFT and/or the first conductive layer CDL1 in the third direction (z-axis direction). The second bottom metal layer BML2 can prevent light from entering the active layer ACT of the thin-film transistor TFT, and may be electrically connected to the thin-film transistor TFT to perform the function of stabilizing the characteristics of the thin-film transistor TFT. The second bottom metal layer BML2 may include the same material as the first bottom metal layer BML1.

The second buffer layer BF2 may be located on the first buffer layer BF1 and the second bottom metal layer BML2. The second buffer layer BF2 may include an inorganic film capable of preventing permeation of air or moisture. For example, the second buffer layer BF2 may include a plurality of inorganic films stacked on one another alternately.

The thin-film transistor TFT may be placed on the second buffer layer BF2. The thin-film transistor TFT may be a driving transistor of the pixel circuit. The thin-film transistor TFT may include an active layer ACT, a source electrode SE, a drain electrode DE and a gate electrode GE.

The active layer ACT may be located on the second buffer layer BF2. The active layer ACT may overlap with the bottom metal layer BML and the gate electrode GE in the third direction (z-axis direction). The active layer ACT may be insulated from the gate electrode GE by the gate insulator GI. The material of parts of the active layer ACT may be made conductive to form the source electrode SE and the drain electrode DE.

The gate electrode GE may be located on the gate insulator GI. The gate electrode GE may overlap with the active layer ACT in the third direction (z-axis direction) with the gate insulator GI interposed between the gate electrode GE and the active layer ACT.

The first conductive layer CDL1 may be spaced apart from the gate electrode GE. The first conductive layer CDL1 may overlap with the bottom metal layer BML in the third direction (z-axis direction) with the gate insulator GI interposed between the first conductive layer CDL1 and the bottom metal layer BML. The first conductive layer CDL1 may be electrically connected to the first bottom metal layer BML1 through a contact hole CNH penetrating the gate insulator GI, the second buffer layer BF2 and the first buffer layer BF1.

The interlayer dielectric layer ILD may cover the gate electrode GE, the first conductive layer CDL1 and the gate insulator GI. The interlayer dielectric layer ILD may include an inorganic film that can prevent permeation of air or moisture. For example, the interlayer dielectric layer ILD may include a plurality of inorganic films stacked on one another alternately.

The second conductive layer CDL2 may be located on the interlayer dielectric layer ILD. The second conductive layer CDL2 may include a variety of lines arranged in the display area DA.

A part of the second conductive layer CDL2 may be electrically connected to a source electrode SE of a thin-film transistor TFT and the second bottom metal layer BML2 through contact holes CNH penetrating the interlayer dielectric layer ILD and the second buffer layer BF2, and another part of the second conductive layer CDL2 may be electrically connected to a drain electrode DE of the thin-film transistor TFT through a contact hole CNH penetrating the interlayer dielectric layer ILD. In addition, yet another part of the second conductive layer CDL2 may be electrically connected to the first conductive layer CDL1 through a contact hole CNH penetrating the interlayer dielectric layer ILD.

The first passivation layer PAS1 may be located on the interlayer dielectric layer ILD and may cover the second conductive layer CDL2. The first passivation layer PAS1 may work as an insulating film and can protect the second conductive layer CDL2.

The third conductive layer CDL3 may be located on the first passivation layer PAS1. The third conductive layer CDL3 may be a connecting electrode that electrically connects the second conductive layer CDL2 with the anode electrode AE. The third conductive layer CDL3 may be electrically connected to the second conductive layer CDL2 through a contact hole CNH penetrating the first passivation layer PAS1.

The second passivation layer PAS2 may be located on the first passivation layer PAS1 and may cover the third conductive layer CDL3. The second passivation layer PAS2 may work as an insulating film and can protect the third conductive layer CDL3.

The display element layer DEL may be located on the thin-film transistor layer TFTL. The display element layer DEL may include light-emitting elements ED, a pixel-defining layer PDL and a spacer SPC.

While the cross-sectional view of a plurality of third light-emitting elements ED3 in the third emission areas EA3 is shown in FIG. 6, the third emission area EA3 will be referred to as the emission area EA, and the third light-emitting element ED3 will be referred to as the light-emitting element ED in the following descriptions.

The light-emitting element ED may be located on the second passivation layer PAS2 and may include an anode electrode AE, an organic layer ORL and a cathode electrode CE.

The anode electrode AE may be located on, i.e., disposed on the second passivation layer PAS2. As used herein, and as mentioned above, an element located on another element should be understood as being disposed on the other element. A plurality of anode electrodes AE may be located in the respective emission areas EA. The anode electrodes AE may be spaced apart from each other.

The anode electrode AE may be a reflective electrode. For example, the anode electrode AE may include a metal layer such as Ag, Mg, Al, Pt, Pd, Au, Ni, Nd, Ir and Cr, and may further include a metal oxide layer stacked on the metal layer.

The organic layer ORL may be located on the anode electrode AE. As described above, the organic layer ORL may be formed in a tandem structure. Accordingly, some parts of the organic layer ORL may be formed as common layers, while the other parts of the organic layer ORL may be formed in the respective emission areas EA such that they are spaced apart from one another.

The cathode electrode CE may be located in contact with the organic layer ORL. The cathode electrode CE may be translucent or transmissive.

In examples where the cathode electrode CE is semi-transmissive, the cathode electrode CE may include Ag, Mg, Cu, Al, Pt, Pd, Au, Ni, Nd, Ir, Cr, Li, Ca, LiF/Ca, LiF/Al, Mo, Time or a compound or a mixture thereof, e.g., a mixture of Ag and Mg.

In examples where the cathode electrode CE is transmissive, the cathode electrode CE may include a transparent conductive oxide (TCO). For example, the cathode electrode CE may be formed of tungsten oxide (WxOy), titanium oxide (TiO₂), indium tin oxide (ITO), indium zinc oxide (IZO), zinc oxide (ZnO), indium tin zinc oxide MgO (magnesium oxide), etc.

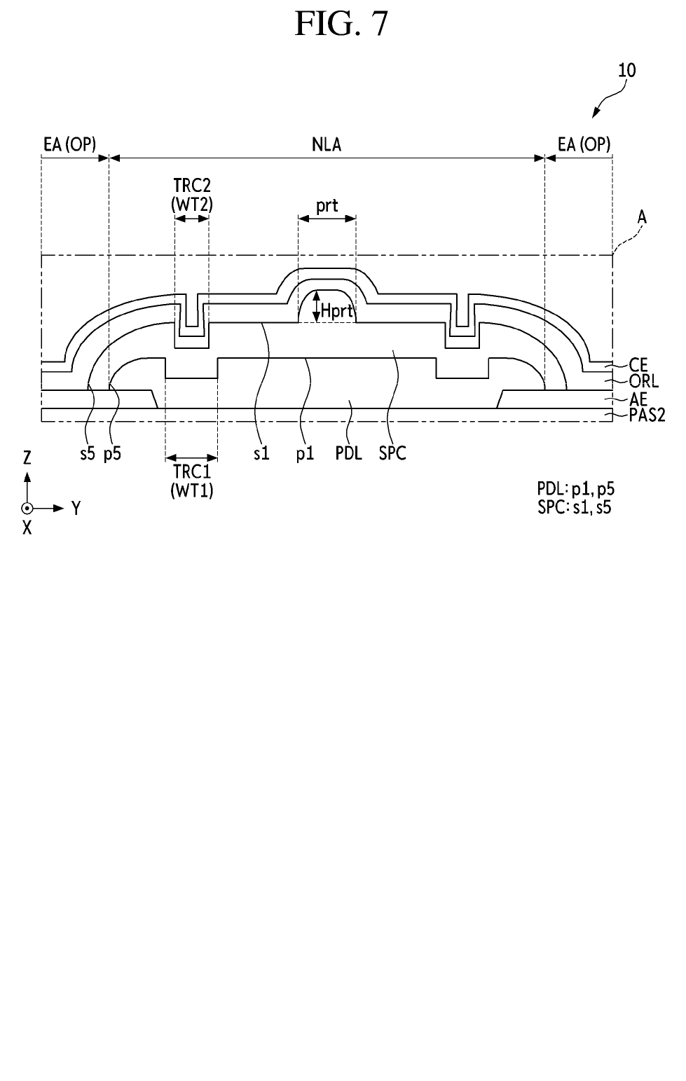

FIG. 7 is an enlarged cross-sectional view of area A of the display area shown in FIG. 6.

Referring to FIGS. 6 and 7 in conjunction with FIGS. 1 to 5, the pixel-defining layer PDL may be located on the second passivation layer PAS2. The pixel-defining layer PDL may be located in the non-emission area NLA.

The pixel-defining layer PDL may define an emission opening OP and may expose the anode electrode AE in the emission opening OP. In other words, the pixel-defining layer PDL may cover the edges of the anode electrode AE.

The pixel-defining layer PDL may separate and insulate the adjacent anode electrodes AE from each other.

The pixel-defining layer PDL may include an organic material. For example, the pixel-defining layer PDL may include an organic material such as an acrylic resin, an epoxy resin, a silicone resin, a phenol resin, a polyamide resin and a polyimide resin.

The pixel-defining layer PDL may define a first trench TRC1. The first trench TRC1 may be located in the non-emission area NLA. The first trench TRC1 may be positioned such that it surrounds the emission opening OP. In other words, the first trench TRC1 may not overlap with the emission opening OP or the emission area EA. For example, the first trench TRC1 may have the shape of the trench TRC shown in FIG. 4 when viewed from the top.

According to the embodiment, and with continued reference to FIG. 7, the pixel-defining layer PDL may include an upper surface p1 and a side surface p5. The upper surface p1 of the pixel-defining layer PDL may face the spacer SPC, and the side surface p5 may be located close to the emission opening OP and may be connected to the upper surface p1.

The first trench TRC1 may refer to a part of the upper surface p1 of the pixel-defining layer PDL that is recessed toward the second passivation layer PAS2 of the transistor layer TFTL. Accordingly, the upper surface p1 of the pixel-defining layer PDL may have a step in the first trench TRC1, i.e., that defines the first trench TRC1. In other words, the first trench TRC1 may refer to a part of the pixel-defining layer PDL that is recessed toward the second passivation layer PAS2.

The spacer SPC may be located on the pixel-defining layer PDL. The spacer SPC may be located in the non-emission area NLA. The spacer SPC can protect the display element layer DEL from external physical impact.

The spacer SPC may include an organic material. For example, the spacer SPC may include an organic material such as an acrylic resin, an epoxy resin, a silicone resin, and a phenol resin.

The spacer SPC may include a second trench TRC2 and a protrusion prt.

The second trench TRC2 may be located in the non-emission area NLA. The second trench TRC2 may be positioned such that it surrounds the emission opening OP. In other words, the second trench TRC2 may be positioned so that it does not overlap with the emission opening OP or the emission area EA.

According to the embodiment, the spacer SPC may include an upper surface s1 and a side surface s5. The upper surface s1 of the spacer SPC may be located on a side of the spacer SPC that is opposite a side of the spacer SPC that faces the pixel-defining layer PDL, and the side surface s5 may be located close to the emission opening OP and may be connected to the upper surface s1. In some examples, the second trench TRC2 may have the shape of the trench TRC shown in FIG. 4 when viewed from the top.

The spacer SPC may completely cover the pixel-defining layer PDL. Specifically, the spacer SPC may be in contact with and cover the upper surface p1 and the side surface p5 of the pixel-defining layer PDL. Accordingly, the upper surface s1 of the spacer SPC may overlap with the upper surface p1 of the pixel-defining layer PDL, and the side surface s5 of the spacer SPC may overlap with the side surface p5 of the pixel-defining layer PDL, e.g., in the z-axis direction.

According to the embodiment, the spacer SPC may cover a part of the anode electrode AE in the emission opening OP and may be in contact with the anode electrode AE.

Accordingly, as shown in FIG. 7, the anode electrode AE according to the embodiment may include a portion in contact with the organic layer ORL, a portion in contact with the spacer SPC and a portion in contact with the pixel-defining layer PDL. The portion of the anode electrode AE in contact with the organic layer ORL and the portion of the anode electrode AE in contact with the spacer SPC may be located in the emission opening OP, while the portion of the anode electrode AE in contact with the pixel-defining layer PDL may be located in the non-emission area NLA.

The second trench TRC2 may refer to a part of the upper surface s1 of the spacer SPC that is recessed toward the pixel-defining layer PDL. Accordingly, the upper surface s1 of the spacer SPC may have a step in the second trench TRC2, i.e., that defines the second trench TRC2. In other words, the second trench TRC2 may refer to a portion of the spacer SPC that is recessed toward the pixel-defining layer PDL.

Typically, in a display device applied to a high-resolution electronic device, a plurality of light-emitting elements ED may be spaced apart from one another within a small area. This may mean that the light-emitting elements ED are spaced apart from one another at a narrow spacing.

For example, when some parts of the organic layer ORL and the cathode electrode CE included the light-emitting elements ED are arranged at a narrow spacing and are formed as common layers, this may cause leakage current defects in the display device 10. As used herein, the above-described common layers mean that some parts of the organic layer ORL and the cathode electrode CE are formed as single connected layers across the emission area EA and the non-emission area NLA, where the emission area EA may be inclusive of many light-emitting elements ED.

The above-mentioned leakage current defects may occur when the electric current for driving at least one pixel among the plurality of pixels arranged at a narrow spacing leaks to an adjacent pixel. The above-described leakage current defects may be caused by a dopant material contained in the organic layer ORL and/or a metal material contained in the cathode electrode CE.

According to the embodiment, as the spacer SPC includes the second trench TRC2, the physical lengths of the organic layer ORL and the cathode electrode CE can be increased through the presence of the second trench TRC2. In addition, the spacer SPC according to the embodiment can control the deposition thickness of the organic layer ORL and the cathode electrode CE so that the thickness of the organic layer ORL and the cathode electrode CE may be relatively low, i.e. small in the second trench TRC2. For example, the deposition thicknesses of the organic layer ORL and the cathode electrode CE is relatively low in the second trench TRC2 because the step coverage of the deposition material may become lower along the sidewalls of the trench during the fabrication process.

Accordingly, the display device 10 according to the embodiment can increase the resistance value of the organic layer ORL and the cathode electrode CE, thereby preventing leakage current defects. Accordingly, even in a high-resolution electronic device employing the display device 10 according to the embodiment, it is possible to prevent the leakage current defects occurring between adjacent light-emitting elements ED because the spacer SPC includes the second trench TRC2.

According to the embodiment, the second trench TRC2 of the spacer SPC and the first trench TRC1 of the pixel-defining layer PDL may overlap each other in the third direction (z-axis direction). As used herein, the third direction (z-axis direction) may refer to as a direction perpendicular to the surface of the substrate SUB.

Referring to FIG. 7, the first trench TRC1 of the pixel-defining layer PDL may have a first width WT1. The first width WT1 of the first trench TRC1 may refer to the width of a recessed portion of the pixel-defining layer PDL in the first direction (x-axis direction) or the second direction (y-axis direction). In some examples, the first width WT1 may be described as being measured in a direction parallel to the substrate SUB.

The second trench TRC2 of the spacer SPC may have a second width WT2. The second width WT2 of the second trench TRC2 may refer to the width of a recessed portion of the spacer SPC in the first direction (x-axis direction) or the second direction (y-axis direction). In some examples, the second width WT2 may be described as being measured in a direction parallel to the substrate SUB.

According to an embodiment of the present disclosure, the first width WT1 may be greater than the second width WT2. In other words, the edge of the surface of the spacer SPC in the second trench TRC2 may overlap with the surface of the pixel-defining layer PDL in the first trench TRC1. Put another way, the surface of the spacer SPC in the second trench TRC2 may not overlap with the outer side of the first trench TRC1 of the pixel-defining layer PDL. Put in yet another way, the second trench TRC2 may be located inside the first trench TRC1 when viewed from the top, and the first trench TRC1 may surround the second trench TRC2 when viewed from the top.

The protrusion prt of the spacer SPC may be located in the non-emission area NLA. The protrusion prt may not overlap with the emission opening OP or the emission area EA.

The protrusion prt may refer to a portion of the spacer SPC that protrudes on one side in the third direction (z-axis direction). The protrusion prt may not overlap with the first trench TRC1 or the second trench TRC2. The protrusion prt may protrude in the opposite direction to the direction in which the second trench TRC2 is recessed. Therefore, the spacer SPC may have a shape in which the recessed portions and the protruding portions alternate.

For example, the height Hprt of the protrusion prt may have, but is not limited to, a value in a range from 0.5 micrometers to 2.5 micrometers.

The protrusion prt of the spacer SPC can protect the display element layer DEL and the thin-film transistor layer TFTL from external physical impact.

The organic layer ORL may be located on the anode electrode AE in the emission area EA, and may be located on the spacer SPC in the non-emission area NLA. The organic layer ORL may be formed along the profile of the protrusion prt and the second trench TRC2 of the spacer SPC. Therefore, the organic layer ORL may include a step in the non-emission area NLA.

The organic layer ORL may be in contact with the spacer SPC in the second trench TRC2. Redundant descriptions of the organic layer ORL are omitted.

According to the embodiment, the organic layer ORL may not be in contact with the pixel-defining layer PDL. In other words, the pixel-defining layer PDL is entirely covered by the spacer SPC, so it may not be in contact with the organic layer ORL.

The cathode electrode CE may be located on the organic layer ORL. The cathode electrode CE may be formed along the profile of the protrusion prt and the second trench TRC2 of the spacer SPC. Therefore, the cathode electrode CE may include a step in the non-emission area NLA. Redundant descriptions of the cathode electrode CE are omitted.

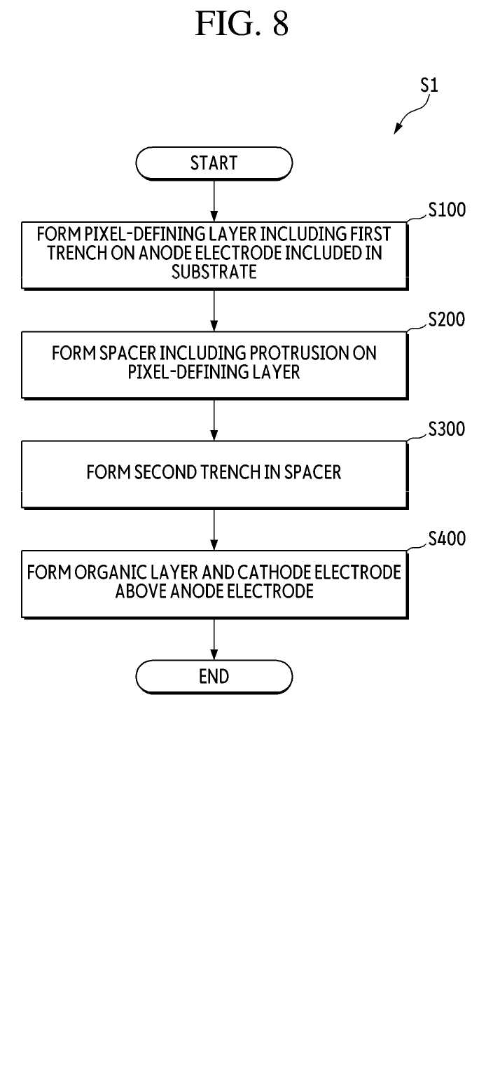

FIG. 8 is a flowchart illustrating steps in a method of fabricating the display element layer in FIG. 6.

Referring to FIG. 8 in conjunction with FIGS. 1 to 7, a method for fabricating a display element layer DEL included in a display device 10 according to an embodiment (S1) may include: forming a pixel-defining layer including a first trench on an anode electrode included in a substrate (step S100); forming a spacer including a protrusion on the pixel-defining layer (step S200); forming a second trench in the spacer (step S300); and forming an organic layer and a cathode electrode on the anode electrode (step S400).

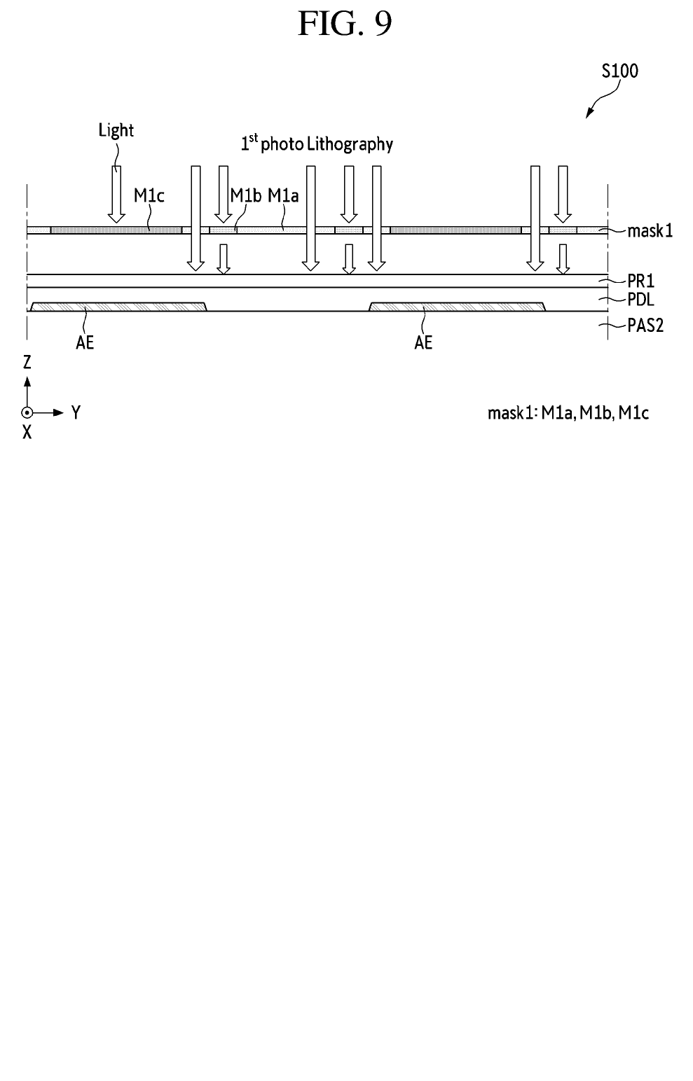

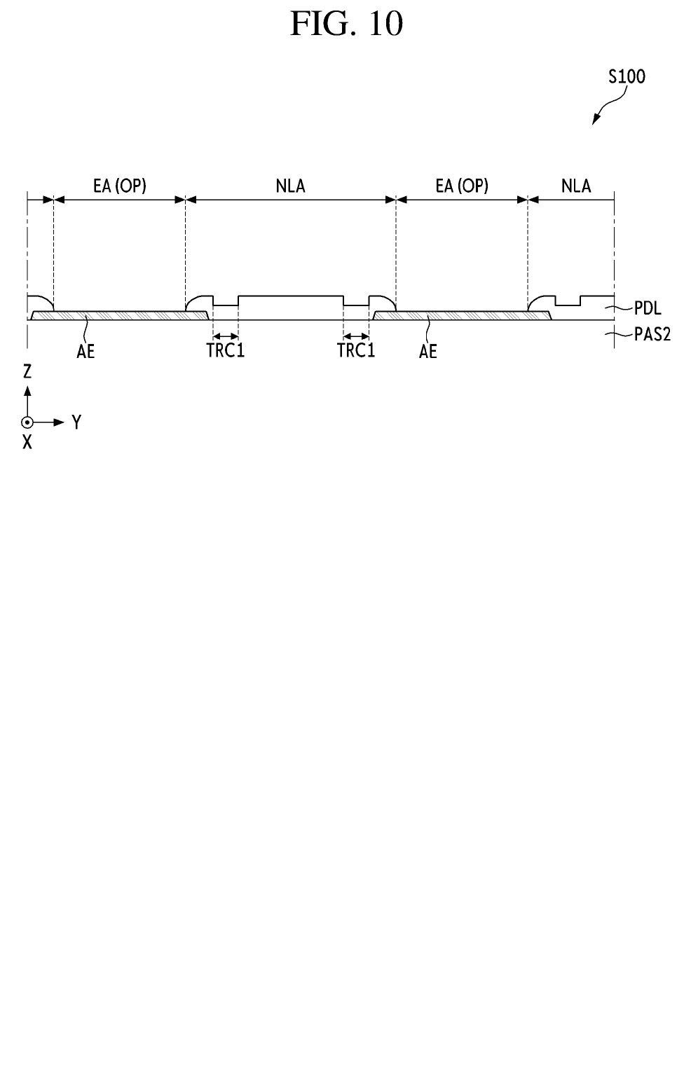

FIGS. 9 and 10 are cross-sectional views showing step S100 of FIG. 8.

Referring to FIGS. 9 and 10 in conjunction with FIGS. 1 to 8, the forming a pixel-defining layer including a first trench on the anode electrode S100 will be described.

First, a plurality of anode electrodes AE are formed on a second passivation layer PAS2, and a pixel-defining layer PDL is formed entirely on the plurality of anode electrodes AE. The pixel-defining layer PDL may be in contact with the plurality of anode electrodes AE and the second passivation layer PAS2.

Although not shown in the drawings, a thin-film transistor layer TFTL including the second passivation layer PAS2 may be located on the substrate SUB. In such arrangements, the detailed structure of the thin-film transistor layer TFTL may be identical to that shown in FIG. 6.

In this process, the process of forming the anode electrode AE may be performed via a film forming process (e.g., a deposition process) that forms at least one of the above-described metal materials and a patterning process.

In this process, the pixel-defining layer PDL may be formed by performing a first photolithography process. For example, the first photolithography process may refer to a process of performing pixel-defining layer coating, photoresist formation, exposure process, development process, etching process and/or photoresist removal process to implement a high-resolution fine pattern.

First, a pixel-defining layer PDL and a photoresist PR1 on the pixel-defining layer PDL are formed. In this process, the photoresist PR1 may be a negative photoresist. Specifically, a portion of the photoresist PR1 that receives light may act as a dissolution inhibitor and may ultimately be preserved, i.e., remain.

Subsequently, after exposure to light in conjunction with the use of a halftone mask mask1, a development process is performed. In this process, the halftone mask mask1 is a mask for controlling the intensity of light, and can adjust the transmittance of light for each region among different regions.

In this process, the halftone mask mask1 may include a first region M1a, a second region M1b and a third region M1c, each of which have distinct characteristics respecting the transmittance of light. Specifically, the first region M1a may transmit 100% of light, and the photoresist PR1 under the first region M1a may receive light to act as a dissolution inhibitor. As a result, photoresist PR1 under the first region M1a may remain after exposure. Further, the second region M1b may transmit 30% to 50% of light, and the photoresist PR1 under the second region M1b may be partially dissolved and removed, leaving some portions. Additionally, the third region M1c may not transmit any light, and the photoresist PR1 under the third region M1c may be entirely dissolved and removed.

Through this process, the resulting photoresist PR1 may have a pattern, and the pixel-defining layer PDL may be patterned using the patterned photoresist PR1. For example, the patterning process may be performed through a dry etching process. For example, the dry etching process may be conducted via a reactive ion etching (RIE) process using a reactive gas such as CHF3, CH3F, CH2F2, CHF6, CF4, C2F6 and C3F6, and sputtering gas such as Ar and O2/Ar. In this instance, an inductively coupled plasma (ICP) source or a capacitively coupled plasma (CCP) source may be used as the plasma source.

### Subsequently, the photoresist PR1 is removed.

Through this process, the pixel-defining layer PDL may be formed to cover the edge of the anode electrode AE, and may define an emission opening OP. In the resultant structure, the emission area EA and the non-emission area NLA may be partitioned by the emission area OP.

Through this process, the pixel-defining layer PDL may define a first trench TRC1. The first trench TRC1 may refer to a part of the pixel-defining layer PDL that is recessed toward the second passivation layer PAS2. The first trench TRC1 may not overlap with the emission opening OP and may be formed in the non-emission area NLA.

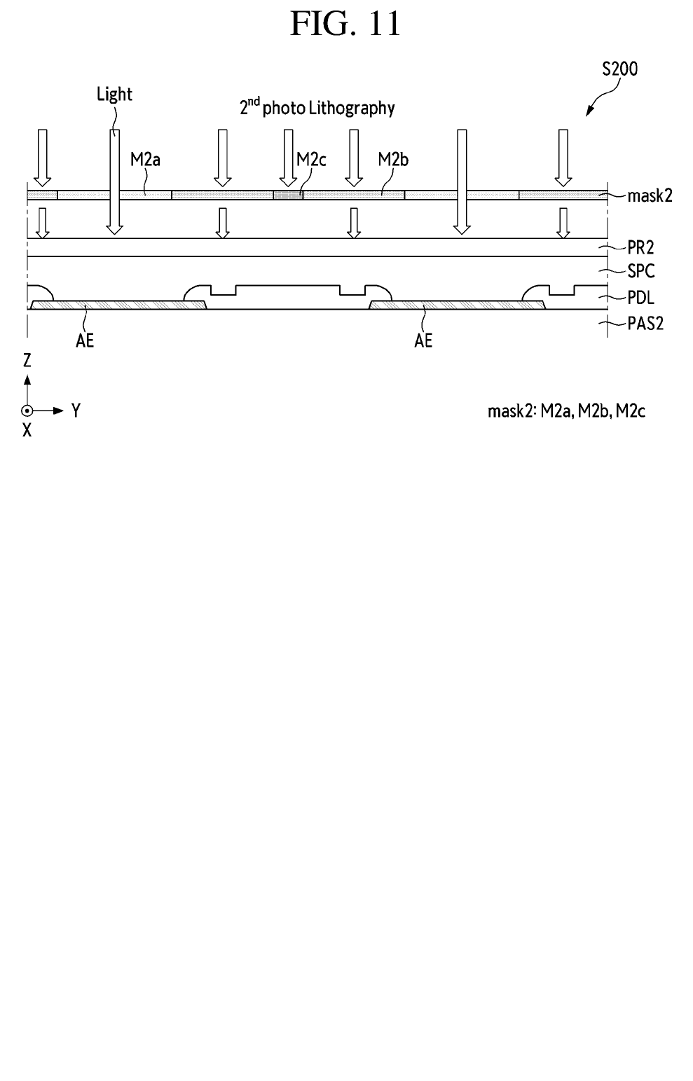

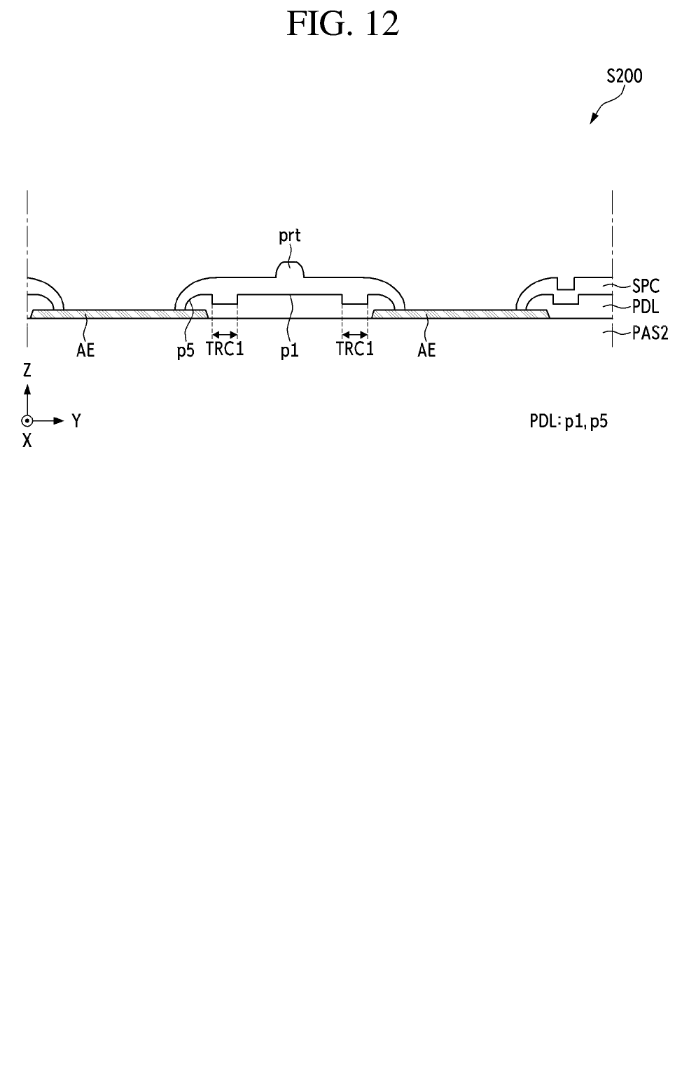

FIGS. 11 and 12 are cross-sectional views showing step S200 of FIG. 8.

Referring to FIGS. 11 and 12 in conjunction with FIGS. 1 to 10, the forming of a spacer including a protrusion on the pixel-defining layer S200 will be described.

Subsequent to formation of the pixel-defining layer PDL, a second photolithography process is performed. For example, the second photolithography process may refer to a process of performing spacer coating, photoresist formation, exposure process, development process, etching process and/or photoresist removal process to implement a high-resolution fine pattern.

First, a spacer SPC and a photoresist PR2 are formed entirely on the pixel-defining layer PDL. In this process, the photoresist PR2 may be a positive photoresist. That is to say, a portion of the photoresist PR2 that receives light may be dissolved.

Subsequently, after exposure to light using a halftone mask mask2, a development process is performed. In this process, the halftone mask mask2 is a mask for controlling the intensity of light, and can adjust the transmittance of light for each region among different regions.

In this process, the halftone mask mask2 may include a first region M2a, a second region M2b and a third region M2c, each of which have distinct characteristics respecting the transmittance of light. Specifically, the first region M2a may transmit 100% of light, and the photoresist PR2 under the first region M2a may receive light and may be completely dissolved. Further, the second region M2b may transmit 30% to 50% of light, and the photoresist PR2 under the second region M2b may be partially dissolved and removed, leaving some portions. Additionally, the third region M2c may not transmit light, and the photoresist PR2 under the third region M2c may not be dissolved but instead may remain.

Through this process, the resultant photoresist PR2 may have a pattern, and the spacer SPC may be patterned using the patterned photoresist PR2. For example, in this process, the patterning process may be performed through a dry etching process.

### Subsequently, the photoresist PR2 is removed.

Through this process, the spacer SPC can include a protrusion prt. The protrusion prt may refer to a portion of the spacer SPC that protrudes toward one side in the third direction (z-axis direction). The first trench TRC1 of the pixel-defining layer PDL may not overlap with the protrusion prt of the pixel-defining layer PDL.

Through this process, the spacer SPC may have a clad structure that entirely covers the pixel-defining layer PDL. Specifically, the spacer SPC may entirely cover the upper surface p1 and the side surface p5 of the pixel-defining layer PDL. The spacer SPC may be further extended so that a part of the spacer SPC may be in contact with the anode electrode AE. The spacer SPC may be in contact with the pixel-defining layer PDL at the first trench TRC1 of the pixel-defining layer PDL.

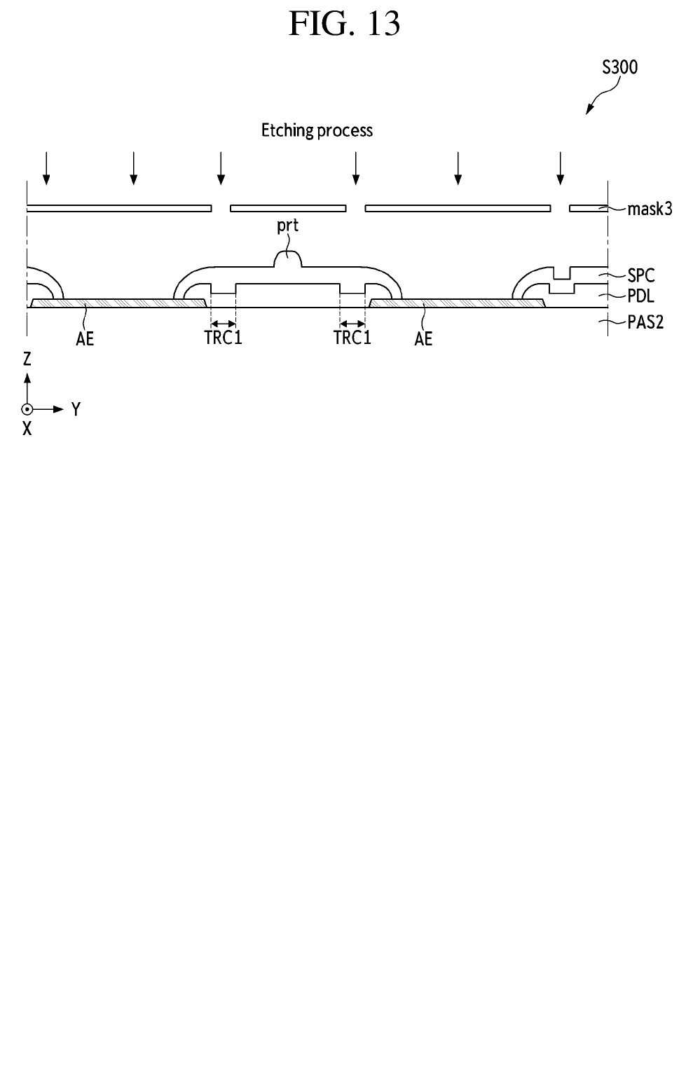

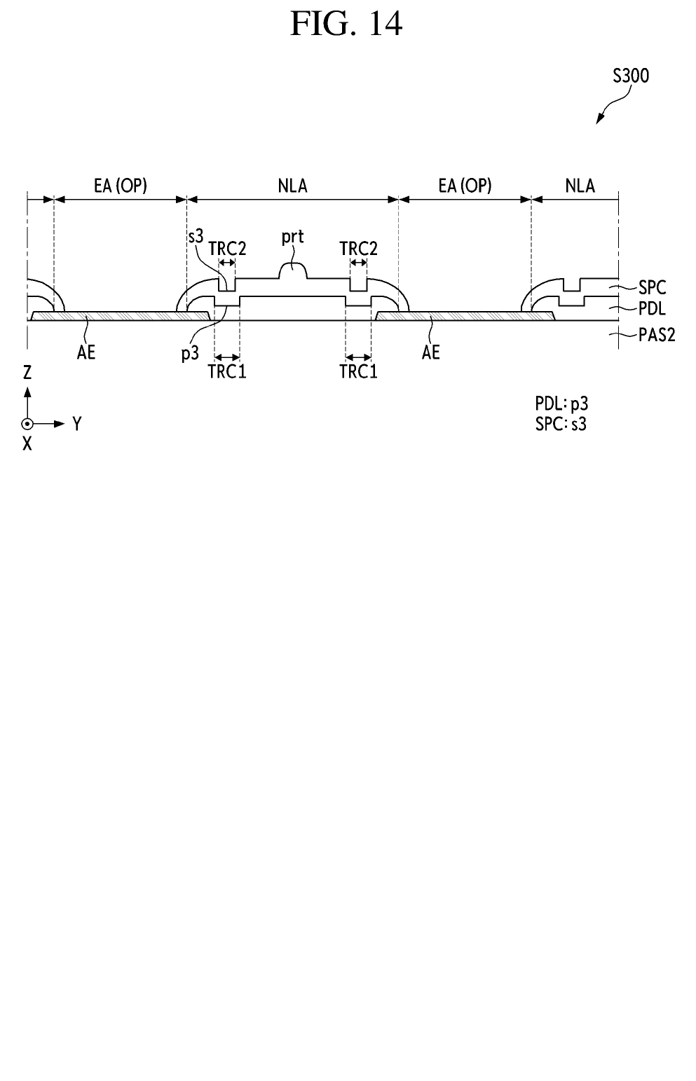

FIGS. 13 and 14 are cross-sectional views showing step S300 of FIG. 8.

Referring to FIGS. 13 and 14 in conjunction with FIGS. 1 to 12, the forming of a second trench in the spacer S300 will be described.

Initially, a mask mask3 is formed above the spacer SPC, and then an etching process is performed. In this process, the etching process may be performed through a dry etching process. Redundant descriptions will be omitted.

Through this process, a portion of the spacer SPC under an open area of the mask mask3 may be removed, such that a second trench TRC2 may be formed.

However, if the pixel-defining layer PDL is exposed during the process of forming the second trench TRC2, this may cause damage to the pixel-defining layer PDL. The damage to the pixel-defining layer PDL may be caused by an etchant used in an etching process or a developer used to remove a photoresist.

Accordingly, in the display device 10 according to the embodiment, the first trench TRC1 of the pixel-defining layer PDL is formed in advance at a location where the second trench TRC2 is to be formed, so that the spacer SPC may have a relatively large thickness in an alignment with the first trench TRC1. Accordingly, because the second trench TRC2 is formed at the location of the first trench TRC1 where the spacer SPC is thicker relative to other areas of the spacer in the display device 10 according to the embodiment, it is possible to prevent damage to the pixel-defining layer PDL caused by exposure of the pixel-defining layer PDL during the process of forming the second trench TRC2.

In addition, as the display device 10 according to the embodiment includes the spacer SPC with a relatively large thickness in the first trench TRC1, the margin of the etching process, e.g., the precision tolerance can be increased during the etching process for forming the second trench TRC2 of the spacer SPC. Therefore, the display device 10 according to the embodiment can be easily fabricated.

In this process, the second trench TRC2 may be in line with the first trench TRC1 in the third direction (z-axis direction). As described above, the width of the second trench TRC2 may be smaller than the width of the first trench TRC1. Redundant descriptions will be omitted.

Referring to FIG. 14, in this process, a surface s3 of the spacer SPC in the second trench TRC2 may overlap with a surface p3 of the pixel-defining layer PDL in the first trench TRC1. The edges of the surface s3 of the spacer SPC in the second trench TRC2 may overlap with the surface p3 of the pixel-defining layer PDL in the first trench TRC1. In other words, the surface s3 of the spacer SPC in the second trench TRC2 may not overlap with the outer sides of the first trench TRC1.

In this process, the second trench TRC2 may not overlap with the protrusion prt of the spacer SPC. Redundant descriptions will be omitted.

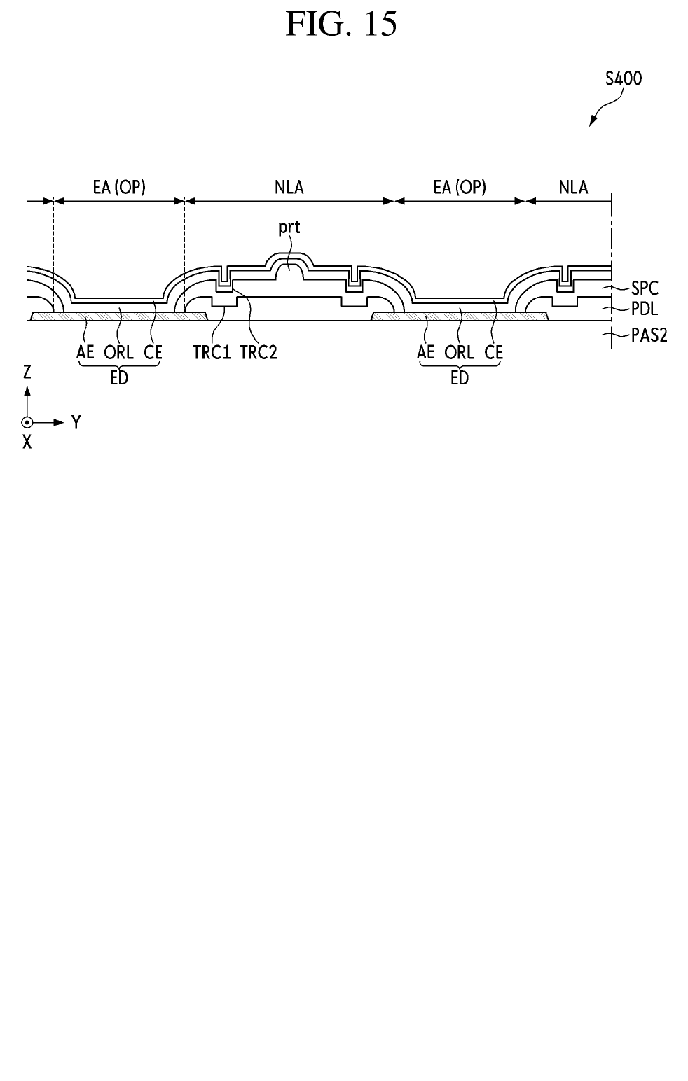

FIG. 15 is a cross-sectional view showing step S400 of FIG. 8.

Referring to FIG. 15 in conjunction with FIGS. 1 to 14, the forming of the organic layer and the cathode electrode on the anode electrode S400 will be described.

First, an organic layer ORL is formed on the anode electrode AE. In this process, some parts of the organic layer ORL may be formed as common layers. In other words, the organic layer ORL may be located on the anode electrode AE in the emission area EA, and may be extended from it to be located on the spacer SPC in the non-emission area NLA, i.e., as one continuous layer. The organic layer ORL may be extended across the emission area EA and the non-emission area NLA.

As described above, according to the embodiment, the physical length of the organic layer ORL may be increased in the second trench TRC2 of the spacer SPC, and the physical thickness may be reduced. Accordingly, the display device 10 according to the embodiment can prevent leakage current defects caused by a dopant material contained in the organic layer ORL. Redundant descriptions will be omitted.

In this process, the cathode electrode CE may be formed as a common layer. In other words, the cathode electrode CE may be formed across the emission area EA and the non-emission area NLA, i.e., as one continuous layer.

As described above, according to the embodiment, the physical length of the cathode electrode CE may be increased in the second trench TRC2 of the spacer SPC, and the physical thickness may be reduced. Accordingly, the display device 10 according to the embodiment can prevent leakage current defects caused by a metal material contained in the cathode electrode CE.

In this manner, the display element layer DEL shown in FIG. 6 can be formed.

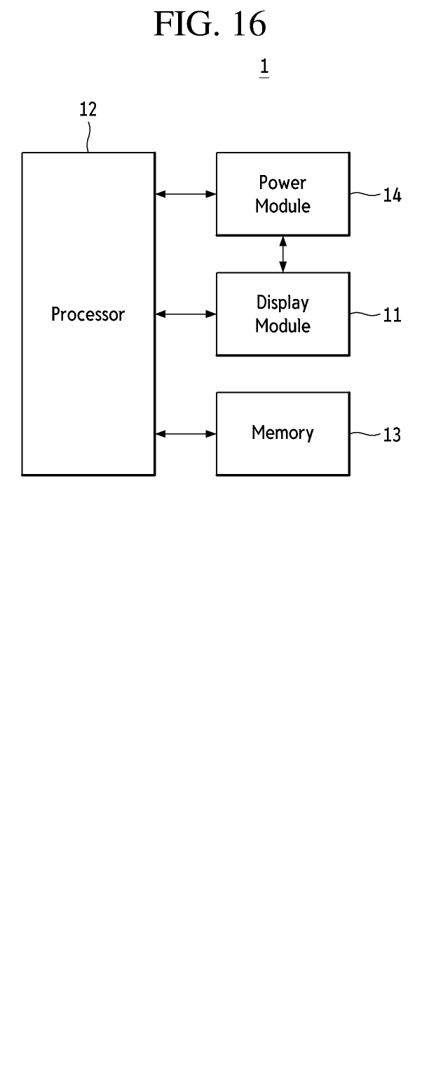

FIG. 16 is a block diagram of an electronic device according to an embodiment of the present disclosure.

Referring to FIG. 16 in conjunction with FIGS. 1 to 15, the display device 10 according to the embodiment may be applied to a variety of electronic devices 1. The electronic device 1 according to the embodiment may include the above-described display device 10, and may further include a module or device having additional functions in addition to the display device 10.

The electronic device 1 according to the embodiment may include a display module 11, a processor 12, a memory 13, and a power module 14.

The processor 12 may include at least one of: a central processing unit (CPU), an application processor (AP), a graphic processing unit (GPU), a communication processor (CP), an image signal processor (ISP), or a controller.

The memory 13 may store data information required for the operation of the processor 12 or the display module 11. When the processor 12 executes an application stored in the memory 13, an image data signal and/or an input control signal may be transmitted to the display module 11. The display module 11 may process the received signal and output image information through a display screen.

The power module 14 may include a power supply module such as a power adapter and a battery device, and a power conversion module that converts the power supplied by the power supply module to generate power required for the operation of the electronic device 1.

At least one of the elements of the electronic device 1 described above may be included in the display devices according to the embodiments described above. In addition, some of the individual modules functioning as a single module may be included in the display device while some others may be provided separately from the display device. For example, the display device may include the display module 11, and the processor 12, the memory 13 and the power module 14 may be implemented as other devices inside the electronic device 1 instead of the display device.

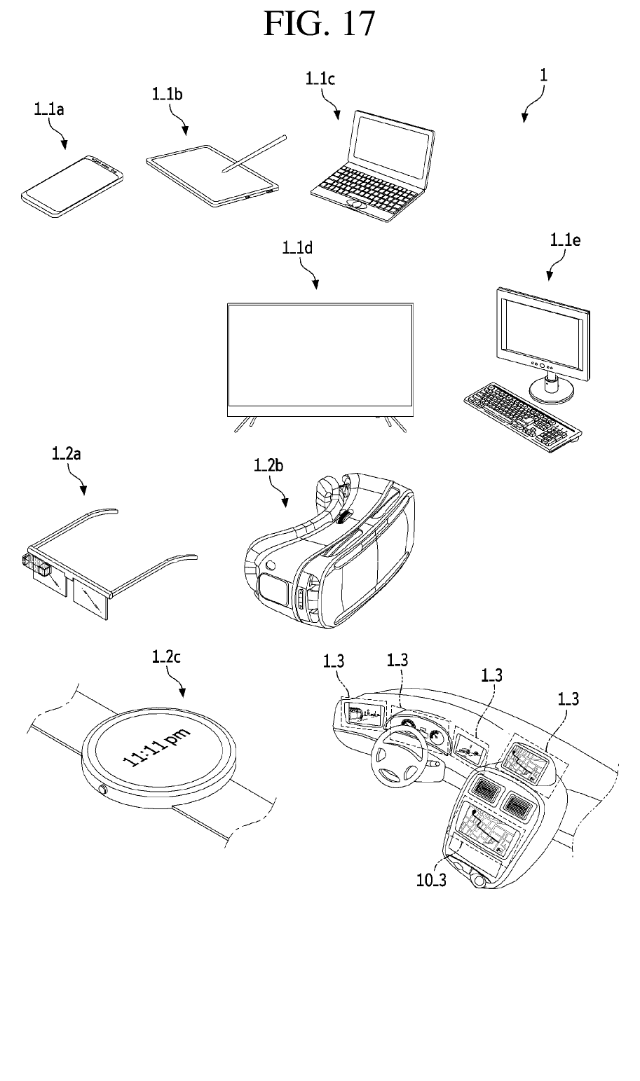

FIG. 17 includes perspective views showing electronic devices according to a variety of embodiments of the present disclosure.

Referring to FIG. 17 in conjunction with FIGS. 1 to 16, a variety of electronic devices 1 employing the display devices 10 according to the embodiments may include not only image display electronic devices such as a smart phone 1_1a, a tablet PC 1_1b, a laptop computer 1_1c, a TV 1_1d and a desktop monitor 1_1e, but also wearable electronic devices including display modules such as smart glasses 1_2a, a head-mounted display 1_2b and a smart watch 1_2c, and electronic devices for vehicles 1_3 including display modules such as a center information display (CID) placed on the dashboard, the center fascia and the dashboard of a vehicle, and a room mirror display.

Embodiments of the disclosure should not be construed as being limited to the embodiments set forth herein. Rather, these embodiments are provided so that this disclosure will be thorough and complete and will fully convey the concept of the present disclosure to those skilled in the art.

While the present disclosure has been particularly shown and described with reference to embodiments thereof, it will be understood by those of ordinary skill in the art that various changes in form and details may be made therein without departing from the spirit or scope of the present disclosure as defined by the following claims.

1. A display device comprising:
a substrate comprising an emission area and a non-emission area;
an anode electrode disposed on the emission area of the substrate;
a pixel-defining layer disposed on the anode electrode and defining a first trench recessed toward the substrate; and
a spacer disposed on the pixel-defining layer and defining a second trench recessed toward the pixel-defining layer,
wherein the first trench and the second trench overlap each other in a first direction perpendicular to a surface of the substrate, and
wherein a width of the first trench is greater than a width of the second trench, the width of the first trench and the second trench being measured in a second direction parallel to the surface of the substrate.

2. The display device of claim 1, wherein the pixel-defining layer covers an edge of the anode electrode, and the pixel-defining layer is entirely covered by the spacer.

3. The display device of claim 2, wherein the pixel-defining layer further comprises:
an upper surface facing the spacer; and
a side surface facing the emission area and connected to the upper surface,
wherein the spacer is in contact with the upper surface of the pixel-defining layer and the side surface of the pixel-defining layer and covers the upper surface of the pixel defining layer and the side surface of the pixel-defining layer.

4. The display device of claim 1, wherein the pixel-defining layer defines an emission opening,
wherein the pixel-defining layer exposes the anode electrode in the emission opening, and
wherein the first trench and the second trench do not overlap with the emission opening.

5. The display device of claim 4, wherein the spacer is in contact with the anode electrode in the emission opening.

6. The display device of claim 5, further comprising:
an organic layer disposed on the anode electrode in the emission opening,
wherein the organic layer is in contact with the spacer, and wherein the organic layer defines a step in the second trench.

7. The display device of claim 6, further comprising:
a cathode electrode disposed over the anode electrode such that the organic layer separates the cathode electrode and the anode electrode,
wherein the cathode electrode defines a step in the second trench.

8. The display device of claim 1, wherein an edge of a surface of the spacer in the second trench overlaps with the first trench in the first direction.

9. The display device of claim 1, further comprising:
a protrusion protruding in the first direction perpendicular to the surface of the substrate,
wherein the first trench and the second trench do not overlap with the protrusion.

10. A method of fabricating a display device, the method comprising:
forming a pixel-defining layer on an anode electrode included in a substrate, the pixel-defining layer defining a first trench therein;
forming a spacer on the pixel-defining layer, the spacer comprising a protrusion;
forming a second trench in the spacer; and
forming an organic layer and a cathode electrode over the anode electrode.

11. The method of claim 10, wherein the forming of the pixel-defining layer further comprises: forming the first trench by a photolithography process using a halftone mask,
wherein the first trench is defined by a portion of the pixel-defining layer that is recessed toward the substrate.

12. The method of claim 10, wherein the forming of the spacer further comprises: forming the protrusion of the spacer by a photolithography process,
wherein the protrusion of the spacer does not overlap with the first trench.

13. The method of claim 10, wherein the forming of the second trench in the spacer further comprises: forming the second trench by performing a dry etching process,
wherein the second trench is defined by a portion of the spacer that is recessed toward the pixel-defining layer.

14. The display device of claim 13, wherein the forming of the second trench in the spacer further comprises: forming the second trench so that the first trench and the second trench overlap each other in a direction perpendicular to a surface of the substrate.

15. The method of claim 14, wherein the forming of the organic layer and the cathode electrode further comprises: forming the organic layer and the cathode electrode so that they overlap with the first trench and the second trench in the direction perpendicular to the surface of the substrate,
wherein the organic layer comprises a tandem structure, and the cathode electrode is a common electrode.

16. An electronic device comprising:
at least one display device comprising a substrate comprising an emission area and a non-emission area; and
at least one of a display module, a processor, a memory or a power module connected to the display device,
wherein the at least one display device comprises:
an anode electrode disposed on the emission area of the substrate;
a pixel-defining layer disposed on the anode electrode and defining a first trench recessed toward the substrate; and
a spacer disposed on the pixel-defining layer and defining a second trench recessed toward the pixel-defining layer,
wherein the first trench and the second trench overlap each other in a first direction perpendicular to a surface of the substrate, and
wherein a width of the first trench is greater than a width of the second trench, the width of the first trench and the second trench being measured in a second direction parallel to the surface of the substrate.

17. The electronic device of claim 16, wherein the pixel-defining layer covers an edge of the anode electrode, and the pixel-defining layer is entirely covered by the spacer.

18. The electronic device of claim 16, wherein the pixel-defining layer defines an emission opening,
wherein the pixel-defining layer exposes the anode electrode in the emission opening, and
wherein the first trench and the second trench do not overlap with the emission opening.

19. The electronic device of claim 18, further comprising:
an organic layer and a cathode electrode located above the anode electrode in the emission opening such that the anode electrode is in between the organic layer and the substrate and in between the cathode electrode and the substrate,
wherein the organic layer is in contact with the spacer, and
wherein the organic layer and the cathode electrode each include a step in the second trench.

20. The electronic device of claim 16, wherein an edge of a surface of the spacer in the second trench overlaps with the first trench in the first direction.
